(19) United States
(12) Patent Application Publication
(10) Pub. No.: US 2005/0142719 A1
(43) Pub. Date: Jun. 30, 2005

(54) Method of fabricating MOS transistor

(75) Inventor: Byeong Ryeol Lee, Seoul (KR)

Correspondence Address: OBLON, SPIVAK, MCCLELLAND, MAIER & NEUSTADT, P.C., 1940 DUKE STREET, ALEXANDRIA, VA, 22314, US

(73) Assignee: DongbuAnam Semiconductor Inc., Seoul (KR)

(21) Appl. No.: 11/024,725

(22) Filed: Dec. 30, 2004

(30) Foreign Application Priority Data
Dec. 30, 2003 (KR) 10-2003-0100510

(51) Int. Cl. H01L 21/336; H01L 29/76; H01L 31/062; H01L 21/8234

(52) U.S. Cl. 438/197; 438/306; 438/303

(57) ABSTRACT

A method of fabricating a MOS transistor includes forming a gate insulating layer on a semiconductor substrate in an active area isolated by a device isolation layer. A gate electrode is formed on a portion of the gate insulating layer. A thin insulating layer is formed to cover a top and a side of the gate electrode. A LDD screen layer is formed on the thin insulating layer. Dopant ions are implanted at high energy through the LDD screen layer to form a deep LDD region in the semiconductor substrate between the gate electrode and the device isolation layer.

### BACKGROUND OF THE INVENTION

(a) Field of the Invention

The present invention relates to a method of fabricating a semiconductor device, and more specifically to a method of fabricating a MOS transistor.

(b) Discussion of the Related Art

Generally, a channel length of a MOS transistor decreases as a size of a semiconductor device decreases. Because known channels have lengths less than 0.13 μm, many efforts have been made to develop shallow junctions and super steep channel doping.

In order to form a source/drain region having the shallow junction structure, LDD (lightly doped drain) ion implantation has been employed. The conventional LDD ion implantation is carried out by forming a gate electrode, depositing a LDD screen film, and implanting dopant ions at lower energy of from about 2 KeV to about 5 KeV.

However, the ion implantation by low energy degrades a yield of doping equipment.

When the shallow junction structure is formed to reduce lateral diffusion, junction loss in silicidation results in drain leakage current equal to that of a transistor.

### SUMMARY OF THE INVENTION

To address the above-described and other problems, the present invention advantageously provides a method of fabricating a MOS transistor including forming a gate insulating layer on a semiconductor substrate in an active area isolated by a device isolation layer. A gate electrode is formed on a portion of the gate insulating layer. A thin insulating layer is formed to cover a top and a side of the gate electrode. A LDD screen layer is formed on the thin insulating layer. Dopant ions are implanted at high energy through the LDD screen layer to form a deep LDD region in the semiconductor substrate between the gate electrode and the device isolation layer.

It is to be understood that both the foregoing general description of the invention and the following detailed description are exemplary, but are not restrictive of the invention.

### BRIEF DESCRIPTION OF THE DRAWINGS

The accompanying drawings, which are included to provide a further understanding of the invention and are incorporated in and constitute a part of this application, illustrate aspects of the invention and together with the description serve to explain the principle of the invention.

FIGS. 1-7 are cross-sectional diagrams showing a method of fabricating a MOS transistor in a semiconductor device according to one embodiment of the present invention.

### DETAILED DESCRIPTION OF THE INVENTION

Reference is made in detail to the embodiments of the present invention illustrated in the accompanying drawings. The same reference numbers are used throughout the drawings to refer to the same or similar parts.

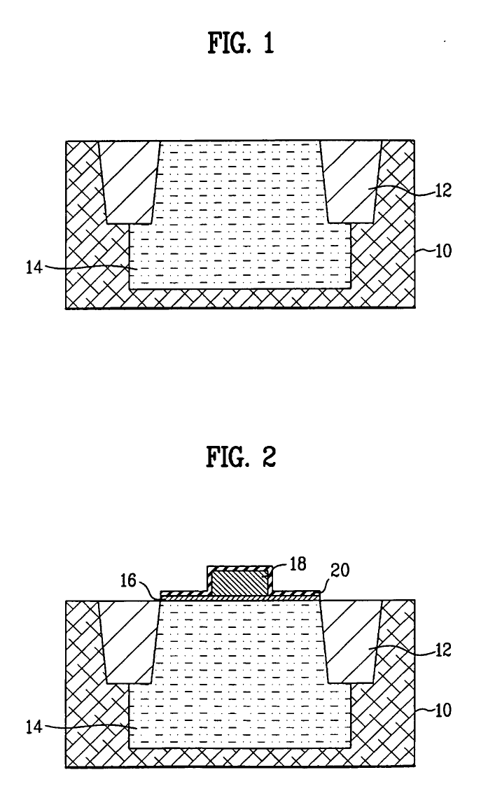

FIGS. 1-7 are cross-sectional diagrams showing a method of fabricating a MOS transistor in a semiconductor device according to the present invention. The MOS transistor can have a relatively deep LDD (lightly doped drain) region.

As shown in FIG. 1, a device isolation layer 12, which isolates an active area and a non-active area from each other, is formed on a semiconductor substrate 10. The layer 12 can be formed by STI (shallow trench isolation) or the like.

A p-well 14, which is lightly doped with a p type dopant, is formed in an area of the semiconductor substrate 10 corresponding to the active area.

As shown in FIG. 2, a gate oxide layer 16 is formed on the semiconductor substrate 10. A gate electrode 18, which is formed of a conductor material such as doped polysilicon, is provided on the gate oxide layer 16 over a portion of the p-well 14.

A silicon oxide layer 20 is formed with a thickness from about 20 Å to about 50 Å. The layer 20 is formed as a thin insulating layer 20 on the gate electrode 18 over the p-well 14. In this case, the thin insulating layer 20 acts as a buffer layer.

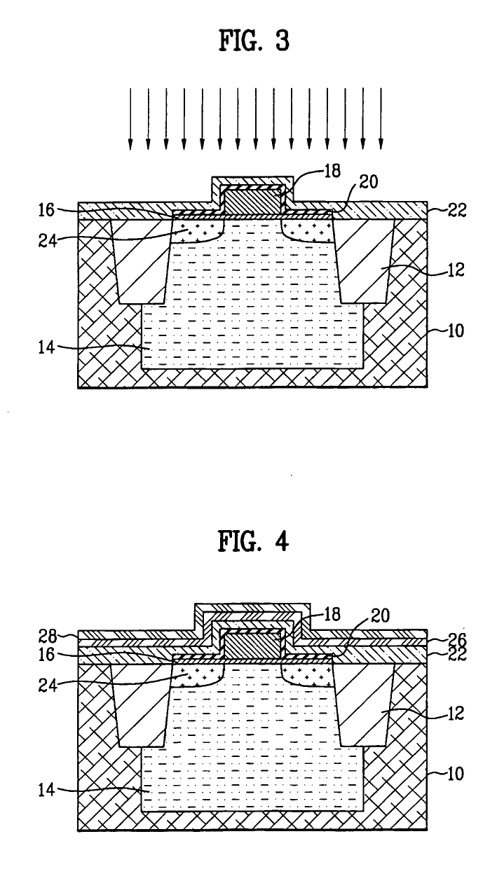

As shown in FIG. 3, a LDD ion implantation screen layer 22 is formed over the semiconductor substrate 10 including the thin insulating layer 20. Preferably, the LDD ion implantation screen layer 22 is formed by depositing a silicon oxide layer having a thickness from about 100 Å to about 300 Å.

LDD ion implantation is performed on the semiconductor substrate at high energy intensity, while using the LDD ion implantation screen layer 22 as a mask. In doing so, P or As used as n type dopant is lightly implanted to form a deep LDD region 24 in the semiconductor substrate 10. The LDD region 24 is formed between the gate electrode 18 and the device isolation layer 12. Preferably, the energy intensity of the LDD ion implantation is from about 10 KeV to about 50 KeV. Thus, by this arrangement, the LDD region 24 is formed deeper from a surface of the semiconductor substrate 10 than the conventional LDD region.

As shown in FIG. 4, a silicon nitride (Si₃N₄) layer is formed as a first insulating layer 26 over the semiconductor substrate 10 having the LDD region 24. A silicon oxide layer is formed as a second insulating layer 28 on the first insulating layer 26.

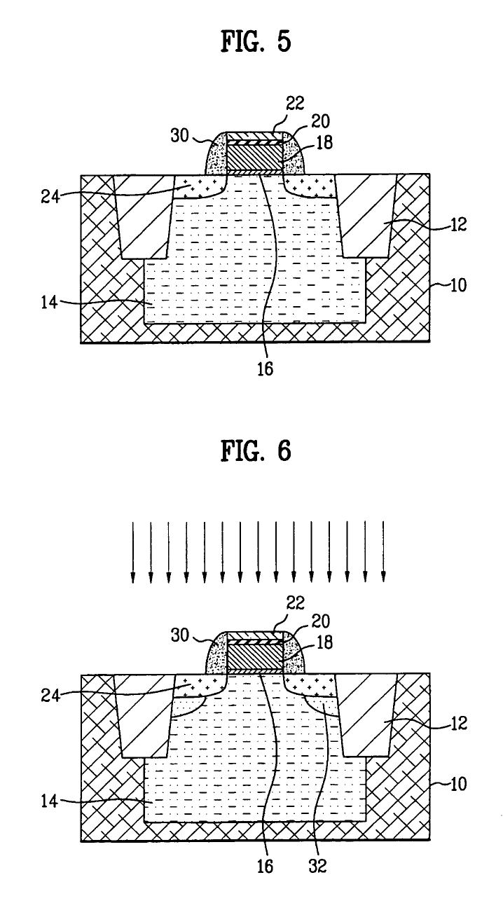

As shown in FIG. 5, the first and second insulating layers 26 and 28 are etched back, such as by dry etching, until the LDD screen layer 22 on the gate electrode 18 is exposed. Thus, a double sidewall spacer 30 is formed on the LDD screen layer 22 provided to the sidewall of the gate electrode 18.

As shown in FIG. 6, source/drain ion implantation is carried out on the semiconductor substrate 10 using the double sidewall spacer 30 as an ion implantation mask. In doing so, P or As ions as n type impurities are relatively heavily implanted to form a source/drain junction in the semiconductor substrate 10. The source/drain junction is formed between the double sidewall spacer 30 and the device isolation layer 12.

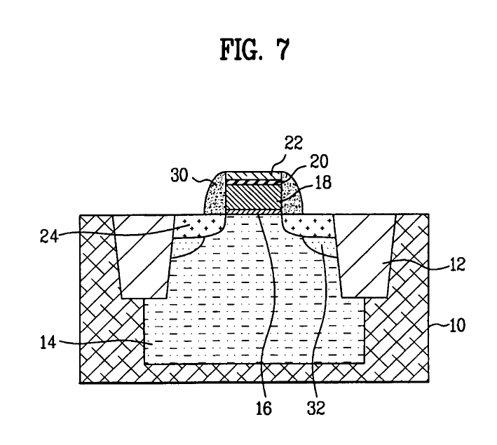

During the LDD ion implantation by the MOS transistor fabricating method according to the present invention, the ion implantation energy is from about 10 KeV to about 50 KeV higher than the range of about 2 to about 5 KeV used in the conventional method. Thus, because the LDD region 24, as shown in FIG. 7, is formed deep from the surface of the semiconductor substrate 10, the LDD region 24 can maintain a shallow junction by the deep LDD region 24 even if a prescribed thickness of the surface of the semiconductor substrate 10 is silicided by performing silicidation on a source/drain junction 32.

In accordance with the present invention, the deep LDD region is formed by forming the thin insulating layer covering the gate electrode, forming the LDD screen layer over the semiconductor substrate, and then implanting dopant ions with high energy of between about 10 KeV to about 50 KeV, whereby a yield of doping equipments is enhanced and whereby drain leakage current of a transistor due to junction loss in silicidation can be prevented.

It will be apparent to those skilled in the art that various modifications and variations can be made in the present invention. Thus, it is intended that the present invention covers the modifications and variations of this invention provided they come within the scope of the appended claims and their equivalents.

The present application incorporates by reference in its entirety Korean Patent Application No. P2003-0100510, filed in the Korean Patent Office on Dec. 30, 2003.

1. A method of fabricating a MOS transistor, comprising the steps of:
forming a gate insulating layer on a semiconductor substrate in an active area isolated by a device isolation layer;
forming a gate electrode on a portion of the gate insulating layer;
forming a thin insulating layer to cover a top and a side of the gate electrode;
forming a LDD screen layer on the thin insulating layer; and
implanting dopant ions at high energy of 10 KeV or higher through the LDD screen layer to form a deep LDD region in the semiconductor substrate between the gate electrode and the device isolation layer.

2. The method according to 1, wherein the step of forming a thin insulating layer includes using silicon oxide.

3. The method according to 2, wherein the step of forming a thin insulating layer includes forming a film having a thickness from about 20 Å to about 50 Å.

4. The method according to 1, wherein the step of forming a LDD screen layer includes using silicon oxide.

5. The method according to 4, wherein the step of forming a LDD screen layer includes forming the LDD screen to have a thickness from about 10 Å to about 300 Å.

6. The method according to 1, wherein the step of implanting dopant ions occurs at a high energy of at most about 50 KeV.

7. The method according to 1, further comprising the steps of:
forming a spacer on the LDD screen layer on a side of the gate electrode; and
forming a source/drain junction in the semiconductor substrate between the spacer and the device isolation layer.

8. The method according to 7, further comprising the step of:
forming a silicide layer on a surface of the deep LDD region.

9. A method of fabricating a MOS transistor, comprising:
step for forming a gate insulating layer on a semiconductor substrate in an active area isolated by a device isolation layer;
step for forming a gate electrode on a portion of the gate insulating layer;
step for forming a thin insulating layer to cover a top and a side of the gate electrode;
step for forming a LDD screen layer on the thin insulating layer; and
step for implanting dopant ions at high energy of 10 KeV or higher through the LDD screen layer to form a deep LDD region in the semiconductor substrate between the gate electrode and the device isolation layer.

10. The method according to 9, wherein the step for forming a thin insulating layer includes using silicon oxide.

11. The method according to 10, wherein the step for forming a thin insulating layer includes forming a film having a thickness from about 20 Å to about 50 Å.

12. The method according to 9, wherein the step for forming a LDD screen layer includes using silicon oxide.

13. The method according to 12, wherein the step for forming a LDD screen layer includes forming the LDD screen to have a thickness from about 10 Å to about 300 Å.

14. The method according to 9, wherein the step for implanting dopant ions occurs at a high energy of at most about 50 KeV.

15. The method according to 9, further comprising:
step for forming a spacer on the LDD screen layer on a side of the gate electrode; and
step for forming a source/drain junction in the semiconductor substrate between the spacer and the device isolation layer.

16. The method according to 15, further comprising:
step for forming a silicide layer on a surface of the deep LDD region.
